(19) United States
(12) Patent Application Publication
(10) Pub. No.: US 2013/0234736 A1
(43) Pub. Date: Sep. 12, 2013

(54) OCCUPANT DETECTION DEVICE

(71) Applicant: DENSO CORPORATION, Kariya-city, (JP)

(72) Inventor: Kouji Ootaka, Toyohashi-city (JP)

(73) Assignee: DENSO CORPORATION, Kariya-city (JP)

(21) Appl. No.: 13/783,721

(22) Filed: Mar. 4, 2013

(30) Foreign Application Priority Data
Mar. 9, 2012 (JP) 2012-052743

(51) Int. Cl. G01R 27/26

(52) U.S. Cl. CPC G01R 27/2605
USPC 324/679

(57) ABSTRACT

An occupant detection device has an electrostatic sensor and a reference sensor device, which are disposed in a seat of a vehicle. The electrostatic sensor includes a detection electrode for generating a capacitance in a space defined by itself and a vehicle body. The reference sensor device has the same detection characteristic as the electrostatic sensor, and is arranged such that it is not affected by a liquid. An occupant determination unit of the detection device determines a presence of an occupant on the seat based on an output of the electrostatic sensor. A determination standard change unit of the detection device changes an occupant determination threshold based on an output of the reference sensor device, where the occupant determination threshold is used by the occupant determination unit for determining the presence of the occupant.

### CROSS-REFERENCE TO RELATED APPLICATION

The present application is based on and claims the benefit of priority of Japanese Patent Application No. 2012-52743, filed on Mar. 9, 2012, the disclosure of which is incorporated herein by reference.

### TECHNICAL FIELD

The present disclosure generally relates to an occupant detection device for detecting an occupant in a vehicle.

### BACKGROUND

An electrostatic sensor disposed in a seat of a vehicle, detects an occupant seated in the seat by detecting capacitance. However, in the event a liquid spill condition in which a liquid, such as water, is spilled onto the seat and absorbed through the seat fabric, the electrostatic sensor ability to detect the occupant may be affected. In Japanese Patent Laid-Open No H07-270541 (JP '541) detection of the occupant in the vehicle is enabled by providing dedicated electrodes for the electrostatic sensor, and by calculating the capacitance between the dedicated electrodes.

However, since the detection device of JP '541 has dedicated electrodes, the cost of the device increases and the device configuration becomes more complex. In addition, the device may not provide sufficient detection accuracy when the humidity around the electrostatic sensor changes. Further, such technique is not capable of detecting a liquid spill condition.

### SUMMARY

In an aspect of the present disclosure, an occupant detection device includes an electrostatic sensor, an occupant determination unit, a reference sensor device, and a determination standard change unit. The electrostatic sensor is disposed in a seat of a vehicle, and has a detection electrode that generates a capacitance with a vehicle body. The reference sensor device is also disposed in the seat, and is arranged such that it is not affected by a liquid. The reference sensor device has the same detection characteristics as the electrostatic sensor, and detects humidity.

The occupant determination unit determines the presence of an occupant at a seat based on an output of the electrostatic sensor. The determination standard change unit changes an occupant determination threshold based on an output of the reference sensor device, where the occupant determination threshold is used by the occupant determination unit for determining the presence of the occupant.

According to the above configuration, the humidity around the occupant detection device is detected by the reference sensor device, which has the same detection characteristics and level of detection as the electrostatic sensor. The reference sensor device is disposed in the seat in a manner that prevents the reference sensor device from being affected by a liquid. Therefore, the humidity is accurately detected when the electrostatic sensor does and does not have a liquid spread thereon.

The occupant determination threshold that is used in the occupant determination unit is changed based on the output of the reference sensor device. Thus, the occupant detection device provides an accurate occupant determination as well as a liquid spill alert to the occupant of the vehicle when a liquid has affected the output of the electrostatic sensor. Accordingly, the occupant detection device accurately detects an occupant of the vehicle without increasing the cost of the device and detects an occupant regardless of the condition of the seat.

### BRIEF DESCRIPTION OF THE DRAWINGS

Other objects, features and advantages of the present disclosure will become more apparent from the following detailed description disposed with reference to the accompanying drawings, in which:

FIG. 1 is a block diagram of an occupant detection device in an embodiment of the present disclosure;

FIG. 2 is an illustration of an electrostatic sensor and a sensor circuit connected thereto of the occupant detection device;

FIG. 3 is an illustration of an equivalent circuit that is representative of a detection object;

FIG. 4 is an illustration of a phase of an electric current that flows in each electrode of the electrostatic sensor;

FIG. 5 is a graph of a sine wave of a signal source and a wave form of an electric current that flows in each of the electrodes of the electrostatic sensor;

FIG. 6 is graph of a conductance and a susceptance according to a seat condition;

FIG. 7 is a graph of a conductance and a susceptance for an adult, a child, and a vacant seat with a control threshold superposed thereon;

FIG. 8 is an illustrative schematic diagram of a sensor circuit at a time of measuring an impedance of the electrostatic sensor;

FIG. 9 is an illustrative schematic diagram of the sensor circuit at a time of measuring a conductance of a reference sensor device;

FIG. 10 is an illustration of the reference sensor device;

FIG. 11 is a side view of the reference sensor device when the reference sensor device is implemented on a wiring board;

FIG. 12 is a partial cross-sectional view of the reference sensor device of FIG. 10 along line XII-XII in FIG. 10; and

FIG. 13 is a flowchart of a detection and control method performed by the occupant detection device.

### DETAILED DESCRIPTION

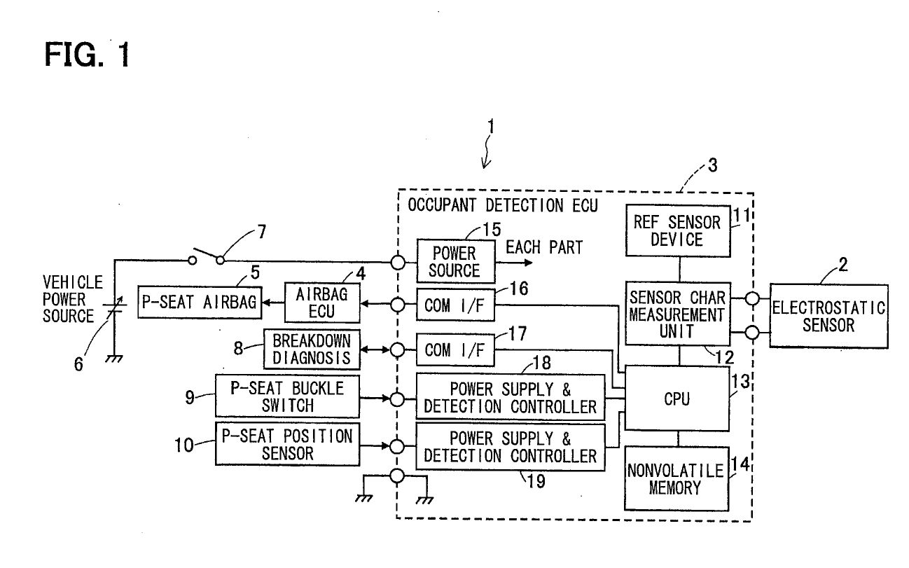

An embodiment of the present disclosure is described with reference to the drawings. With reference to FIG. 1, an occupant detection device 1 includes an electrostatic sensor 2, an occupant detection ECU 3, an airbag ECU 4, and a passenger seat airbag 5 (P-seat airbag).

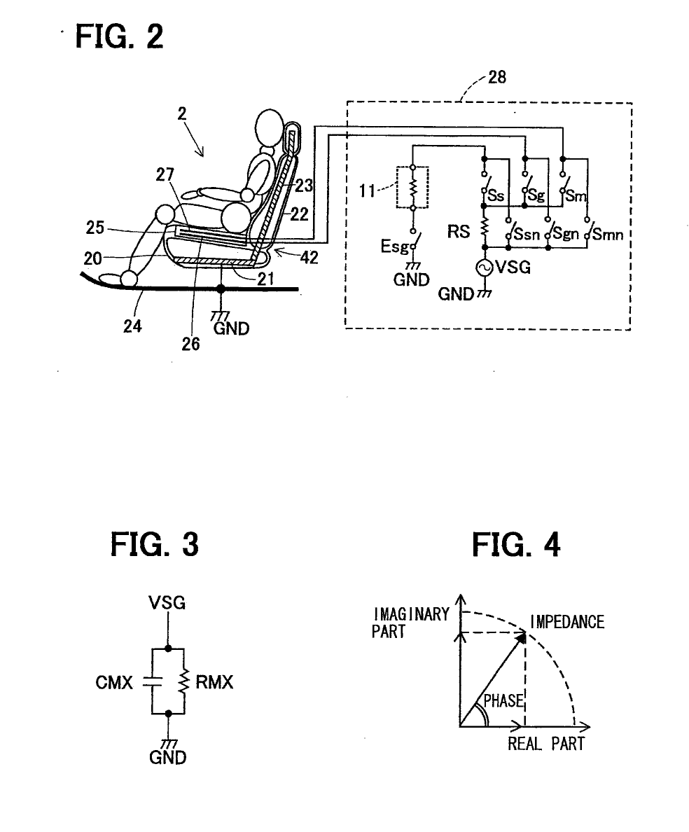

With reference to FIG. 2, the electrostatic sensor 2 includes a seat 42, a sensor mat 25, a seat frame 21, and a back frame 23. The seat 42 includes a seat bed 20 for accommodating a hip of the occupant and a back portion 22 for accommodating a back of the occupant. The sensor mat 25 is disposed between a seat surface and a seat cushion of the seat bed 20, and has a guard electrode 26 and a main electrode 27 inserted therein.

The seat frame 21 is disposed on a bottom surface of the seat bed 20. The back frame 23 is disposed at a center of the back portion 22. The seat frame 21 and the back frame 23 that is connected to the seat frame 21 are conductive to a vehicle body 24, and are grounded to such body. The guard electrode 26 and the main electrode 27 are respectively connected to a sensor circuit 28 by a connection wiring such as a wire harness, and the sensor circuit 28 forms a part of the occupant detection ECU 3.

Capacitance is formed between the main electrode 27 and the seat frame 21 and between the main electrode 27 and the back frame 22. An electric line of force is formed based on a sine wave 37 supplied by a signal source Vsg of the sensor circuit 28. The guard electrode 26 is attached on a lower side of the main electrode 27, and the guard electrode 26 has the sine wave 37 directly applied thereto with the same phase as a sine wave applied to the main electrode 27. Therefore, the electric line of force is only generated on an upper side of the main electrode 27 (i.e., the side of the main electrode 27 facing the seat surface on which the occupant sits), and is not generated on the lower side of the main electrode 27. The capacitance is thus formed between the vehicle body 24 and the main electrode 27, which serves as a detection electrode of the electrostatic sensor 2.

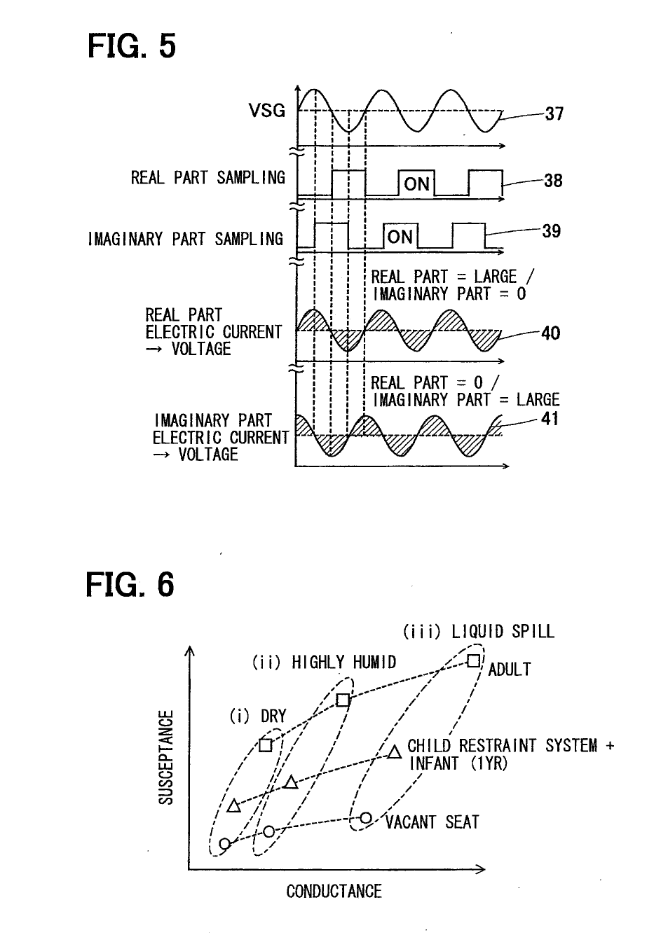

With reference to FIGS. 3-5, an equivalent circuit of the detection object, such as a person or a cup, which is detected by the electrostatic sensor 2, may be represented by a parallel circuit of a resistor RMX (a real part: a conductance) and a capacitance CMX (i.e., an imaginary part: a susceptance). Therefore, the detection of the detection object by using the electrostatic sensor 2 is actually a detection of an impedance having a real part and an imaginary part.

When a signal having the sine wave 37 is applied from the signal source Vsg of the sensor circuit 28 to the electrostatic sensor 2, an electric current detection resistor Rs in the sensor circuit 28 has a voltage difference generated therein, according to an impedance of the detection object. In such a case, when the impedance of the detection object has the real part only, the generated voltage difference in the electric current detection resistor Rs does not include a phase-advance factor relative to the sine wave 37 of the signal source Vsg. Therefore, when the generated voltage difference in the electric current detection resistor Rs is sampled at a real-part sampling timing 38, which has the same phase as the sine wave 37, the result is an output 40 that is solely proportional to the size of the real part.

Further, when the impedance of the detection object has the imaginary part only, the generated voltage difference in the electric current detection resistor Rs has a phase-advance factor relative to the sine wave 37 of the signal source Vsg. Therefore, when the generated voltage difference in the electric current detection resistor Rs is sampled at an imaginary-part sampling timing 39 that has a phase advance of 90 degrees relative to the sine wave 37 of the signal source Vsg, the result is an output 41 that is solely proportional to the size of the imaginary part. Since the actual detection object may have both of the real part and the imaginary part, the actually-measured impedance has a phase illustrated in FIG. 4.

The sensor circuit 28, which is part of a sensor characteristic measurement unit 12 of the occupant detection ECU 3, detects an electric line of force of the capacitance that is generated by the detection object sitting on the seat 42 of the electrostatic sensor 2. For the purpose of measuring an impedance of the electrostatic sensor 2, the electric line is detected as a voltage difference based on an electric current flowing from the signal source Vsg to the electric current detection resistor Rs of the sine wave 37. The sensor characteristic measurement unit 12 outputs the measured impedance as an analog signal that has the real part of the measured impedance and the imaginary part of the measured impedance separated from each other. A CPU 13 then converts such analog signal into a digital signal and processes the converted digital signal. In such case, the sensor characteristic measurement unit 12 may also be configured to output the digital signal instead of the analog signal.

With continuing reference to FIG. 1, the occupant detection device 1 includes a vehicle power source 6 that supplies electric power to a power source 15 of the occupant detection ECU 3, and a switch 7. A passenger seat buckle switch 9 is connected to the CPU 13 of the occupant detection ECU 3 through a power supply & detection controller 18. The passenger seat buckle switch 9 provides information related to the fastening or non-fastening of the buckle by the occupant (i.e., fastening state information).

A passenger seat's position sensor 10 is connected to the CPU 3 of the occupant detection ECU 3 through a power supply & detection controller 19. The passenger seat position sensor 10 provides position information regarding a front-rear positioning (e.g., a sliding position) of the passenger seat to the airbag ECU 4. A deployment speed of the passenger seat airbag 5 may be controlled based on the position information.

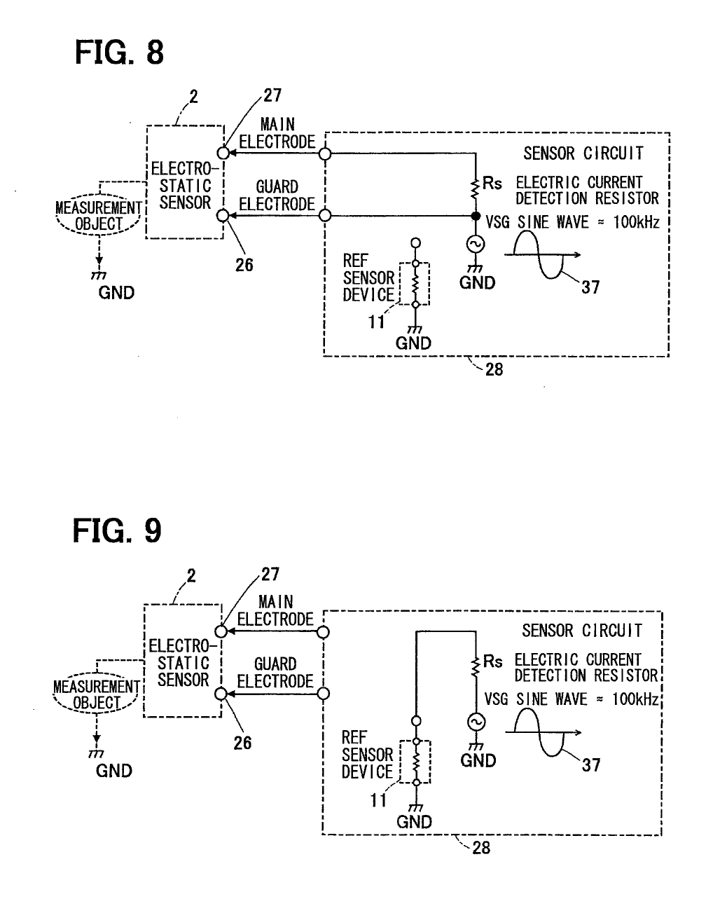

The occupant determination is performed based on a relationship illustrated in FIG. 6. The relationship of FIG. 6 is measured by using a circuit shown in FIG. 8, and shows a general load characteristic of an occupant, who is a detection object of the device. The value of the imaginary part and the value of the real part respectively change according to a seat condition regarding dryness, such as (i) a dry condition, (ii) a moisture absorbed and highly humid condition, and (iii) a liquid spill condition.

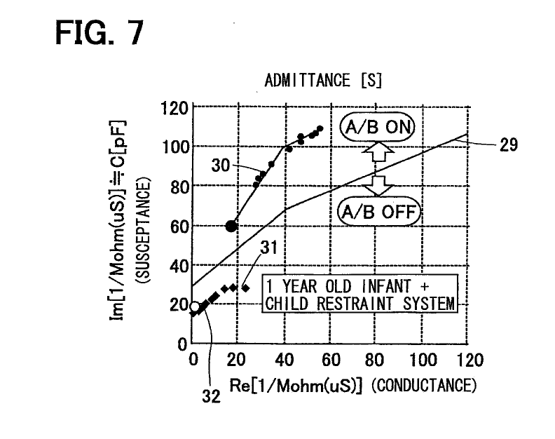

The measurement results by using the sensor characteristic measurement unit 12 are shown in FIG. 7. Data 30 shows a sample of an occupant who is an adult female having a small stature. Data 31 shows a sample of an occupant who is a child sitting on a child seat. Data 32 shows a sample of vacancy, i.e., when the passenger seat is not occupied.

The CPU 13 performs an occupant determination based on the comparison between the data 30, 31, 32 and an occupant determination threshold 29 that is stored in a nonvolatile memory 14. The result of the occupant determination is output to the airbag ECU 4 through communication interface (I/F) 16 or to a breakdown diagnosis 8 through communication interface (I/F) 17.

When the measurement data exceeds the threshold 29, such as the data 30, the CPU 13 outputs an airbag deployment signal for the deployment of the passenger seat airbag 5 from the airbag ECU 4, which is indicated as “A/B ON” in FIG. 7. When the measurement data does not exceed the threshold 29, such as data 31 and data 32, the CPU 13 does not output the airbag deployment signal for the deployment of the passenger seat airbag 5 from the airbag ECU 4 which is indicated as “A/B OFF” in FIG. 7.

As described above, the occupant determination relying on one axis, i.e., only on the imaginary part component, is improved by relying on two axes, i.e., on the imaginary part and the real part, which may be further improved by using a reference sensor device 11. That is, in a specific situation, the occupant determination relying on the two axes may still be difficult, and such a difficulty may be resolved by an improved accuracy that is realized by the use of the reference sensor device 11 under control of the occupant detection ECU 3.

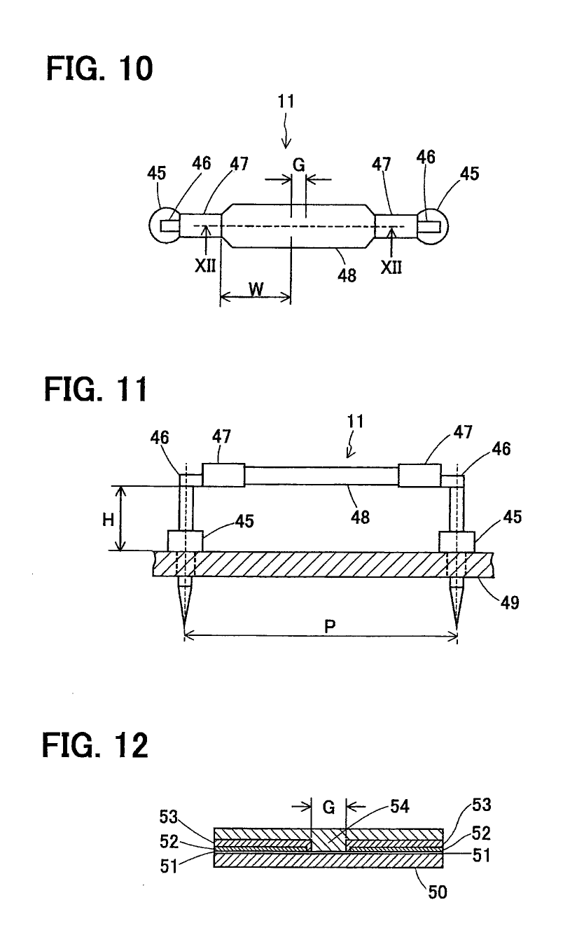

With reference to FIGS. 10 and 11, the reference sensor device 11 is implemented on a wiring board 49 of the occupant detection ECU 3. The reference sensor device 11 has substantially the same configuration and humidity detection characteristic (i.e., the same real part characteristic) as the main electrode 27.

Since the reference sensor device 11 should be in the same humidity environment as the main electrode 27, the device 11 is disposed in the seat 42. Therefore, the occupant detection ECU 3 accommodating the reference sensor device 11 does not have a sealed structure, that is, the reference sensor device 11 has a structure that is susceptible to the ambient humidity. However, the ECU 3 has a position setting of the reference sensor device 11, which does not allow liquid to soak the reference sensor device 11.

Thus, the reference sensor device 11 is easily disposed due to its disposal in the occupant detection ECU 3, in a space-saving manner. However, the reference sensor device 11 may be disposed separately from the ECU 3 at a position in the seat 42, which is not susceptible to a liquid spill, and can be connected to the occupant detection ECU 3 through wiring.

The reference sensor device 11 has a lead 46 that is inserted into the wiring board 49 via a terminal 45 to which the lead 46 is affixed to. The reference sensor device 11 also has the electrode 47 that is disposed on a tip of the lead 46, which has an L-bent shape, and a main body 48 that is disposed between two leads 46.

The terminal 45 is made of a material having (C2600+Sn+Au) or the like. With reference to FIG. 12, the main body 48 is formed to have a gap G interposed between a silver film 52 and a carbon film 53 that are attached on a main film 50 by using an adhesive 51, with a cover film 54 covering the carbon film 53. The size of the gap G is calculated based on the impedance detection characteristic of the electrostatic sensor 2, and may preferably be a value of 0.5 to 2 mm. The humidity of the environment is detected by having water deposited on the gap G, which leads to the change of a resistance value of the sensor device 11. Such a structure of the electrode having the carbon film 53 and the gap G is same as the structure of the main electrode 27.

With continuing reference to FIGS. 10 and 11, the width W of the electrode is calculated from the impedance detection characteristic of the electrostatic sensor 2, and may preferably be a value of about 2 mm. The implementation height H may preferably be equal to or greater than 5 to 10 mm, for decreasing the influence of a parasitic capacitance, which may be formed with the wiring board 49. The parasitic capacitance may also be formed with an object above or beside the main body 48. Therefore, such object above/beside the main body 48 should be disposed at a distance of at least 5 to 10 mm from the body 48, if such object is made of metal. The implementation pitch P may preferably be a value of about 20 mm, in consideration of the element implementation density of the wiring board and the deterioration of the implemented parts due to the warpage of such parts. The cover film 53 may be, for example, a PET film having a thickness of 40 micron.

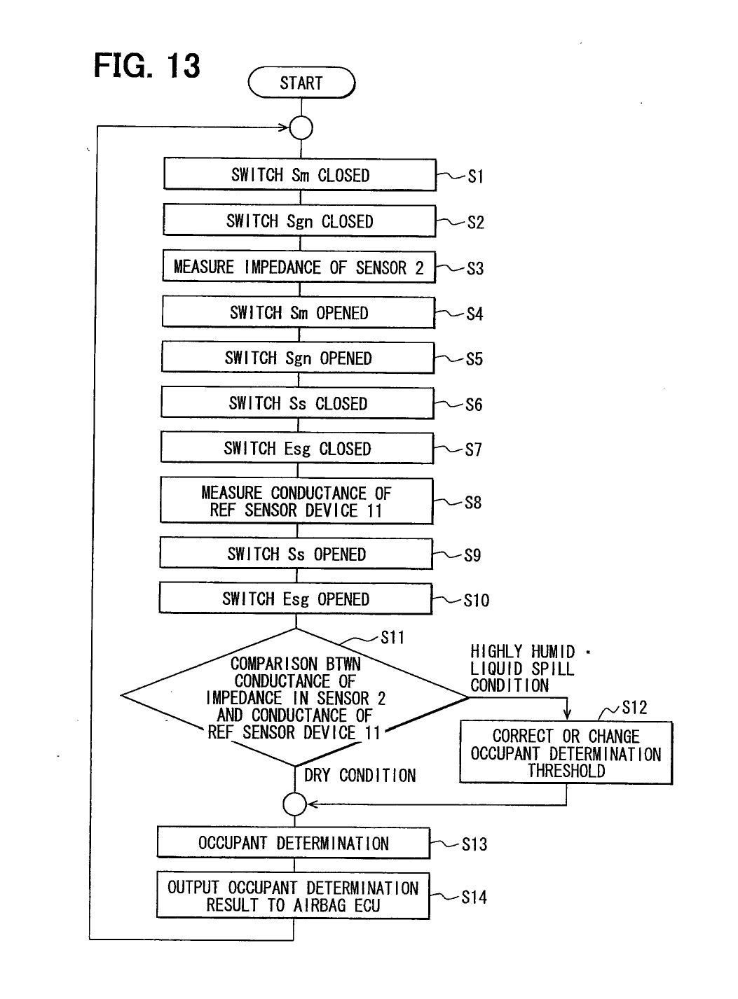

With reference to the drawings, the operation of the vehicular occupant detection device that uses the reference sensor device 11 is described. The process of FIG. 13 is performed by the occupant detection ECU 3.

Firstly, in S1, a switch Sm is closed to apply the sine wave 37 to the main electrode 27 through the electric current detection resistor Rs (FIG. 2), thereby enabling the impedance measurement of the electrostatic sensor 2. At S2, a switch Sgn is closed to directly apply the sine wave 37 to the guard electrode 26, thus enabling the impedance measurement of the electrostatic sensor 2.

Subsequently, at S3, the sensor circuit 28 is put in a state shown in FIG. 8, and the impedance of the electrostatic sensor 2 is measured. At such moment, the sine wave 37 of the signal source Vsg is directly applied to the guard electrode 26. In such manner, the main electrode 27 and the guard electrode 26 have the same voltage, and the impedance of the lower side of the main electrode 27 is cancelled. In other words, the impedance of the main electrode 27 towards the guard electrode 26 and seat cushion of the seat bed 20 is cancelled. Therefore, the impedance measurement is enabled only towards the seat surface of the seat bed 20 (i.e., the upper side of the main electrode 2), thereby allowing detection of an occupant on the seat 42.

At S4, the switch Sm is opened to stop the impedance measurement of the electrostatic sensor 2. The switch Sgn is opened, at S5, to stop the impedance measurement of the electrostatic sensor 2.

The conductance measurement of the reference sensor device 11 is then enabled by closing a switch Ss to apply the sine wave 37 to the reference sensor device 11 through the electric current detection resistor Rs at S6. The conductance measurement of the reference sensor device 11 is enabled by closing a switch Esg at S7. Subsequently, the sensor circuit 28 is put in a state shown in FIG. 9, and the conductance of the reference sensor device 11 is measured at S8. The switch Ss is then opened to stop the conductance measurement of the reference sensor device 11 at S9. The switch Esg is opened, at S10, to stop the conductance measurement of the reference sensor device 11.

The real part of the impedance value (i.e., the conductance) of the electrostatic sensor 2 measured at S3 and the conductance value of the reference sensor device 11 measured at S8 are compared with each other by the CPU 13 at S11. When the difference between both values is comparatively small or when the conductance value of the reference sensor device 11 measured at S8 is less than a first predetermined value, the electrostatic sensor 2 is determined to be in a dry condition. The occupant determination is then performed based on the threshold 29 in FIG. 7 at S13, and the occupant determination result is provided to the airbag ECU 4 at S14.

When the conductance value of the reference sensor device 11 measured at S8 is greater than a second predetermined value, which is greater than the first predetermined value, the electrostatic sensor 2 and its environment is determined to have an increased humidity level (i.e., highly humid). Accordingly, the imaginary part of the detection value from the electrostatic sensor 2 is corrected, or the threshold 29 is corrected at S12. A corrected threshold that is derived by correcting the threshold 29 of FIG. 7 is used to perform the occupant determination at S13, and the occupant determination result is provided to the airbag ECU 4 (S14). Such a determination may be performed by, for example, correcting (e.g., increasing or decreasing) the value of the threshold 29 to be closer to one of data values among the data 30, 31 of FIG. 7, which is higher than the other, since the higher one of the data 30, 31 is distant from the threshold 29. By performing such a correction, the occupant determination in a high humidity condition has an improved accuracy.

Also, if the conductance value of the reference sensor device 11 measured at S8 is less than the second predetermined value but greater than the first predetermined value, the electrostatic sensor 2 and its environment is determined to be humid, and the threshold 29 or the imaginary part of the detection value from the electrostatic sensor 2 is corrected. When the electrostatic sensor 2 has a liquid spill thereon, the conductance value of the electrostatic sensor 2 takes an extremely high value, thereby resulting in an extremely great difference between the conductance of the electrostatic sensor 2 measured at S3 and the conductance of the reference sensor device 11 measured at S8. When the difference between the conductance of the electrostatic sensor 2 and the conductance of the reference sensor device 11 exceeds a third predetermined value, the electrostatic sensor 2 is determined to have a liquid spilled thereon (i.e., a liquid spill condition) and S12 is performed. At S12, the imaginary part of the detection value of the electrostatic sensor 2 is corrected (e.g., increasing or decreasing per FIG. 7), or the threshold 29 is corrected. At such moment, a spill alert may be provided to the occupant from the device.

The corrected threshold that is derived by correcting the threshold 29 of FIG. 7 is used to perform the occupant determination at S13, and the occupant determination result is provided to the airbag ECU 4 (S14). In such manner, as readily understood from FIG. 6 and FIG. 7, the liquid spill is clearly and unambiguously determined, and the accuracy of the occupant determination is improved, as well as enabling the abnormality warning.

The first, second, and third predetermined values serve as a determination setting standard for determining the correct setting of the threshold 29, which is to be used in the occupant determination performed at S13. In addition, the first, second, and third predetermined values may be appropriately determined according to the characteristics of the sensor mat 25 and the reference sensor device 11, and may be stored in the nonvolatile memory 14.

The sensor circuit 28 includes the switch Ss, a switch Sg, the switch Sm, a switch Ssn, the switch Sgn, a switch Smn, and the switch Esg. These switches are used to switch the object electrodes to be measured, and are also used to perform the breakdown diagnosis of the occupant detection device.

From the above description, the occupant detection device 1 in the present embodiment enables the detection of the humidity of the environment by the reference sensor device 11, which is performed with the same level of detection characteristics as the detection by the electrostatic sensor 2, and the reference sensor device 11 is disposed in the seat 42 in a manner that avoids the liquid spill. Therefore, the occupant detection device 1 can accurately detect the humidity of the environment when the electrostatic sensor 2 does not have the liquid spill condition, and can change the occupant determination threshold 29 that is used by an occupant determination (S13) based on the output of the reference sensor device 11. Thus, the occupant detection device 1 enables an accurate occupant determination, as well as providing a liquid spill alert for alerting the occupant of the vehicle about the spill of liquid over the electrostatic sensor 2. The occupant determination performed at S13 may be referred to as an occupant determination unit.

Further, since the reference sensor device 11 is used for the measurement of only the real part, which is different from how the main electrode 27 is used, the reference sensor device 11 has a simple structure, with fewer design restrictions. Therefore, the production cost of the vehicular occupant detection device 1 is decreased.

Since the reference sensor device 11 can be disposed in the occupant detection ECU 3, such configuration leads to a space saving of the vehicular occupant detection device 1. In addition, since the reference sensor device 11 has two electrodes facing each other with the gap G interposed therebetween, and outputs the capacitance between those electrodes, the reference sensor device 11 can perform the humidity detection with the same level of detection characteristics as the detection performed by the electrostatic sensor 2.

Further, since the reference sensor device 11 upholds the film having the above electrodes formed thereon by using the lead 46 above the wiring board 49 at a predetermined height from the surface of the board 49 in a gap-reserving manner, i.e., separately from the surface of the board 49, the influence of the parasitic capacitance, which may be formed with the wiring board 49, is avoided.

Further, a determination standard change unit (i.e., provided as the process of S11 and S12 of FIG. 13) changes the occupant determination threshold when the conductance value of the reference sensor device 11 exceeds a predetermined conductance value, the occupant determination threshold can securely be changed for the accurate occupant determination when the humidity of the environment is increased.

Further, since the determination standard change unit changes the occupant determination threshold when the difference between the conductance value of the electrostatic sensor 2 and the conductance value of the reference sensor device 11 exceeds a predetermined value, the occupant determination standard can securely be changed for the accurate occupant determination when the humidity of the environment is increased.

Further, since the determination standard change unit can correct the imaginary part of the output of the electrostatic sensor 2, the accurate occupant determination can be performed without changing the occupant determination threshold 29 even when the humidity of the environment is increased.

Further, since (i) the occupant determination unit 3 (i.e., S13) is configured to determine an occupant on the seat 42 based on a comparison between the output of the electrostatic sensor 2 and the occupant determination threshold 29 and (ii) the determination standard change unit corrects the occupant determination threshold 29, an accurate occupant determination can be performed without changing the imaginary part of the output of the electrostatic sensor 2 even when the humidity of the environment is increased.

Although the present disclosure has been fully described in connection with the preferred embodiment thereof with reference to the accompanying drawings, it is to be noted that various changes and modifications will become apparent to those skilled in the art, and such changes and modifications are to be understood as being within the scope of the present disclosure as defined by the appended claims.

What is claimed is:

1. An occupant detection device comprising:
an electrostatic sensor disposed in a seat and having a detection electrode for generating a capacitance with a vehicle body;
an occupant determination unit determining a presence of an occupant at a seat based on an output of the electrostatic sensor;
a reference sensor device disposed in the seat and having a same detection characteristic as the electrostatic sensor for detecting humidity, wherein the reference sensor device is positioned such that it is not affected by a liquid; and
a determination standard change unit changing an occupant determination threshold based on an output of the reference sensor device, the occupant determination threshold being used by the occupant determination unit for determining the presence of the occupant.

2. The occupant detection device of claim 1, wherein the reference sensor device is disposed in an occupant detection ECU that includes the occupant determination unit.

3. The occupant detection device of claim 1, wherein the reference sensor device has two electrodes that face each other with a gap interposed therebetween, and outputs the capacitance between the two electrodes.

4. The occupant detection device of claim 3, wherein the reference sensor device has the electrodes formed on a film.

5. The occupant detection device of claim 4, wherein the film is held by a lead that implements the film above a wiring board at a predetermined height from a surface of the wiring board in a gap-reserving manner.

6. The occupant detection device of claim 1, wherein the determination standard change unit changes the occupant determination threshold when a conductance value of the reference sensor device is greater than a predetermined conductance value.

7. The occupant detection device of claim 1, wherein the determination standard change unit changes the occupant determination threshold when a difference between a conductance value of the electrostatic sensor and a conductance value of the reference sensor device exceeds a predetermined value.

8. The occupant detection device of claim 1, wherein the determination standard change unit corrects an imaginary part of the output of the electrostatic sensor.

9. The occupant detection device of claim 1, wherein the occupant determination unit determines the presence of the occupant based on a comparison between the output of the electrostatic sensor and the occupant determination threshold.
